(19) United States
(12) Patent Application Publication
(10) Pub. No.: US 2024/0015935 A1
(43) Pub. Date: Jan. 11, 2024

(54) SUPPORTIVE COMPOSITE PLATE, FABRICATION METHOD OF THE SUPPORTIVE COMPOSITE PLATE, AND DISPLAY MODULE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Rongkun Chen, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/618,427

(22) PCT Filed: Oct. 25, 2021
(86) PCT No.: PCT/CN2021/126144

§ 371 Date: Dec. 10, 2021

(30) Foreign Application Priority Data
Sep. 30, 2021 (CN) 202111159641.8

(51) Int. Cl. H05K 7/20; G06F 1/20

(52) U.S. Cl. CPC H05K 7/20509; G06F 1/203; G06F 2200/203

(57) ABSTRACT

The present embodiment proposes a supportive composite plate, a fabrication method of the supportive composite plate, and a display module. The supportive composite plate applied to a foldable display panel. The supportive composite plate includes a rigid supportive layer and a heat-dissipation layer. The rigid supportive layer includes a first planar portion, a second planar portion, and a bending portion arranged between the first planar portion and the second planar portion. The heat-dissipation layer, embedded in the rigid supportive layer, comprises a first heat-dissipation portion corresponding to the first planar portion, a second heat-dissipation portion corresponding to the second planar portion, and a bridge portion corresponding to the bending portion. The first heat-dissipation portion is connected to the second heat-dissipation portion via the bridge portion.

### BACKGROUND

### 1. Field of the Disclosure

The present disclosure relates to the field of display technology, and more particularly, to a supportive composite plate, a fabrication method of the supportive composite plate, and a display module.

### 2. Description of the Related Art

With the development of technology, the appearance of mobile electronic equipment has changed a lot. The unique characteristics and huge potential of a flexible screen of the mobile electronic equipment, especially a foldable smart device, has received a lot of attention.

A supportive layer of a display screen in a dynamic foldable (DF) module screen of the related art is usually made of stainless steel. Stainless steel as a kind of material mainly enhances the highness of the screen in the non-bending portion and avoids seriously poor appearance resulting from a process such as bending. In addition, a heat-dissipation layer with higher thermal conductivity is bonded behind the stainless steel as the material to help dissipate heat additionally. However, the composite structure formed by the supportive layer and the heat-dissipation layer after undergoing a bonding process is thicker overall, which is difficult to meet design requirements of a display module like lightweight.

Therefore, there is an urgent need for a supportive composite plate, a fabrication method of the supportive composite plate, and a display module to deal with the above-mentioned technical problems properly.

### SUMMARY

### Technical Problem

An obstacle to a supportive composite plate of the related art adopted in a foldable display device is that the overall thickness of the supportive composite plate is greater.

### Technical Solution

One objective of an embodiment of the present disclosure is to provide a supportive composite plate applied to a foldable display panel. The supportive composite plate includes a rigid supportive layer and a heat-dissipation layer. The rigid supportive layer includes a first planar portion, a second planar portion, and a bending portion arranged between the first planar portion and the second planar portion. The heat-dissipation layer, embedded in the rigid supportive layer, comprises a first heat-dissipation portion corresponding to the first planar portion, a second heat-dissipation portion corresponding to the second planar portion, and a bridge portion corresponding to the bending portion. The first heat-dissipation portion is connected to the second heat-dissipation portion via the bridge portion.

In the supportive composite plate, the rigid supportive layer comprises a first supportive layer and a second supportive layer. The heat-dissipation layer is disposed between the first supportive layer and the second supportive layer. A thickness of the heat-dissipation layer is greater than a thickness of the first supportive layer or a thickness of the second supportive layer.

In the supportive composite plate, a plurality of first openings are disposed on the first supportive layer in a first direction vertical to the heat-dissipation layer; a plurality of second openings are disposed on the second supportive layer in the first direction; both of the first opening and the second opening are disposed in the bending portion.

In the supportive composite plate, the first opening penetrates the first supportive layer and exposes a surface of the heat-dissipation layer which is near the first supportive layer; the second opening penetrates the second supportive layer and exposes a surface of the heat-dissipation layer which is near the second supportive layer. Each of the first openings is displaced with each of the adjacent second openings in the first direction.

In the supportive composite plate, the first opening along a central line of the first direction coincides with the second opening along the central line of the first direction.

In the supportive composite plate, a plurality of third openings are disposed in the bridge portion in the first direction; the third opening along the central line of the first direction coincides with the second opening along the central line of the first direction.

In the supportive composite plate, a spacing between the two adjacent first openings is to 1 times of a length of the first opening in the first direction.

In the supportive composite plate, a material for the rigid supportive layer is stainless steel, aluminum (Al), and titanium (Ti). Material for the heat-dissipation layer is copper (Cu) and silver (Ag).

Another objective of an embodiment of the present disclosure is to provide a fabrication method of a supportive composite plate. The fabrication method includes stacking a heat-dissipation layer on a first supportive layer; stacking a second supportive layer on a side of the heat-dissipation layer away from the first supportive layer; rolling the first supportive layer, the heat-dissipation layer, and the second supportive layer with a physical compression technique to form a first composite plate; and patterning the first composite plate arranged in a bending portion to form the supportive composite plate.

In the fabrication method, a thickness of the heat-dissipation layer is greater than a thickness of the first supportive layer or a thickness of the second supportive layer.

In the fabrication method, a material for the first supportive layer and for the second supportive layer is stainless steel, aluminum (Al), and titanium (Ti); a material for the heat-dissipation layer is copper (Cu) and silver (Ag).

Another objective of an embodiment of the present disclosure is to provide a display module. The display module comprises a supportive composite plate and a display panel arranged on the supportive composite plate. The supportive composite plate includes a rigid supportive layer and a heat-dissipation layer. The rigid supportive layer includes a first planar portion, a second planar portion, and a bending portion arranged between the first planar portion and the second planar portion. The heat-dissipation layer, embedded in the rigid supportive layer, comprises a first heat-dissipation portion corresponding to the first planar portion, a second heat-dissipation portion corresponding to the second planar portion, and a bridge portion corresponding to the bending portion. The first heat-dissipation portion is connected to the second heat-dissipation portion via the bridge portion.

In the display module, the rigid supportive layer comprises a first supportive layer and a second supportive layer. The heat-dissipation layer is disposed between the first supportive layer and the second supportive layer. A thickness of the heat-dissipation layer is greater than a thickness of the first supportive layer or a thickness of the second supportive layer.

In the display module, a plurality of first openings are disposed on the first supportive layer in a first direction vertical to the heat-dissipation layer; a plurality of second openings are disposed on the second supportive layer in the first direction; both of the first opening and the second opening are disposed in the bending portion.

In the display module, the first opening penetrates the first supportive layer and exposes a surface of the heat-dissipation layer which is near the first supportive layer; the second opening penetrates the second supportive layer and exposes a surface of the heat-dissipation layer which is near the second supportive layer. Each of the first openings is displaced with each of the adjacent second openings in the first direction.

In the display module, the first opening along a central line of the first direction coincides with the second opening along the central line of the first direction.

In the display module, a plurality of third openings are disposed in the bridge portion in the first direction; the third opening along the central line of the first direction coincides with the second opening along the central line of the first direction.

In the display module, a spacing between the two adjacent first openings is 0.5 to 1 times of a length of the first opening in the first direction.

In the display module, a material for the rigid supportive layer is stainless steel, aluminum (Al), and titanium (Ti). Material for the heat-dissipation layer is copper (Cu) and silver (Ag).

In the display module, the display module further comprises an adhesive layer; the adhesive layer is arranged between the supportive composite plate and the display panel. Material for the adhesive layer is a solid-state optical glue.

### Advantageous Effects

A heat-dissipation layer is embedded in the rigid supportive layer in the supportive composite plate. The rigid supportive layer and the heat-dissipation layer are integrally formed with a physical compression technique. Without affecting the function of a foldable display panel, the overall thickness of the supportive composite plate is thinned in addition to the function of good support, thereby, reducing the weight of the supportive composite plate.

### BRIEF DESCRIPTION OF THE DRAWINGS

FIG. 1 illustrates a supportive composite plate applied to a foldable display panel according to a first embodiment of the present disclosure.

FIG. 2 illustrates a supportive composite plate applied to a foldable display panel according to a second embodiment of the present disclosure.

FIG. 3 illustrates a flowchart of a fabrication method of a supportive composite plate according to another embodiment of the present disclosure.

FIG. 4A and FIG. 4B illustrate schematic diagrams of the shaped supportive composite plate according to another embodiment of the present disclosure.

### DETAILED DESCRIPTION OF THE EMBODIMENTS

An object of the present disclosure is to deal with the problems of the related art that a display panel arranged in a terminal area of a display module of the related art is prone to wrinkles and then cracking during a bending process.

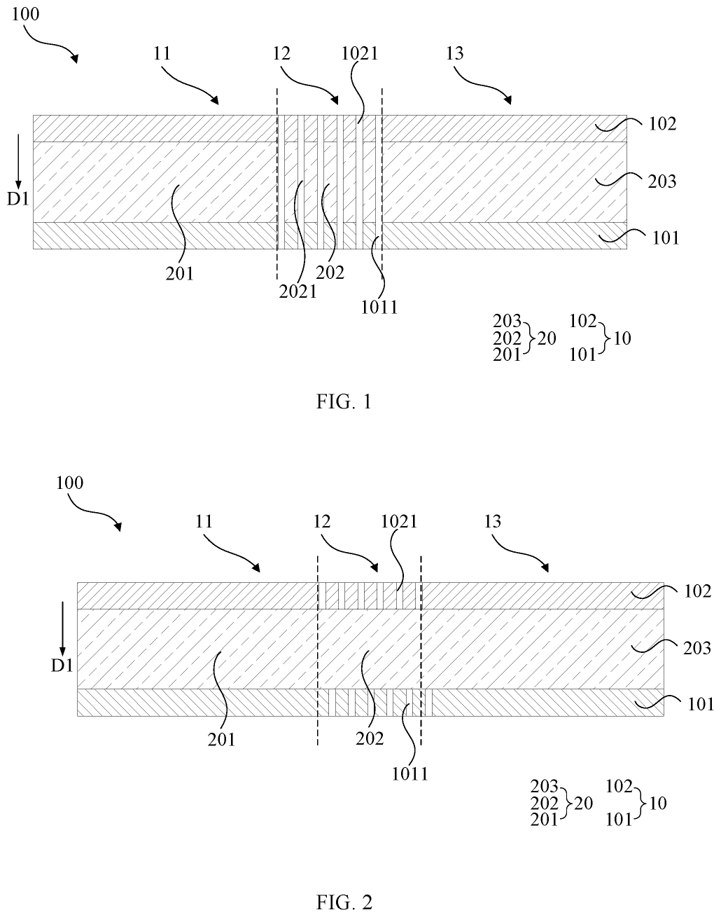

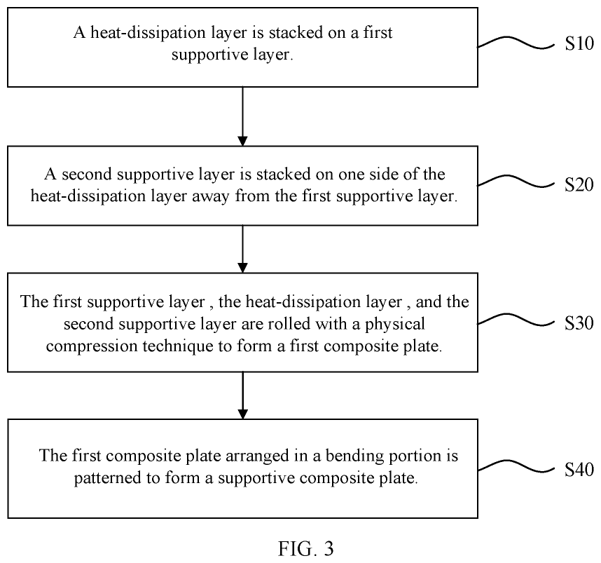

Please refer to FIG. 1 to FIG. 2 illustrating a supportive composite plate 100 which is applied to a foldable display panel. The supportive composite plate 100 includes a rigid supportive layer 10 and a heat-dissipation layer 20. The rigid supportive layer 10 includes a first planar portion 11, a second planar portion 13, and a bending portion 12 arranged between the first planar portion 11 and the second planar portion 13. A heat-dissipation layer 20 is embedded in the rigid supportive layer 10. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202.

A heat-dissipation layer 20 is embedded in the rigid supportive layer 10 in the supportive composite plate 100. The rigid supportive layer 10 includes a first planar portion 11, a second planar portion 13, and a bending portion 12 arranged between the first planar portion 11 and the second planar portion 13. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202. The first supportive layer 101, the heat-dissipation layer 20, and the second supportive layer 102 form the supportive composite plate 100 after being integrally formed with a physical compression technique. Without affecting the function of a foldable display panel, the overall thickness of the supportive composite plate 100 is thinned in addition to the function of good support, thereby, reducing the weight of the supportive composite plate 100.

### Embodiment 1

Please refer to FIG. 1 illustrating a schematic diagram of a supportive composite plate 100 according to a first embodiment of the present disclosure. The supportive composite plate 100 is applied in a foldable display panel. The supportive composite plate 100 includes a rigid supportive layer 10 and a heat-dissipation layer 20. The rigid supportive layer 10 includes a first planar portion 11, a second planar portion 13, and a bending portion 12 arranged between the first planar portion 11 and the second planar portion 13. A heat-dissipation layer 20 is embedded in the rigid supportive layer 10. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202.

The rigid supportive layer 10 includes a first supportive layer 101 and a second supportive layer 102. The heat-dissipation layer 20 is disposed between the first supportive layer 101 and the second supportive layer 102. The rigid supportive layer 10 is mainly used for support and bending. The heat-dissipation layer 20 is mainly used to dissipate heat.

Further, the first supportive layer 101, the heat-dissipation layer 20, and the second supportive layer 102 form the supportive composite plate 100 after being integrally formed with a physical compression technique, which effectively reduces the thickness of the supportive composite plate 100 in a bonding process.

The thickness of the heat-dissipation layer 20 is greater than the thickness of the first supportive layer 101 or the thickness of the second supportive layer 102, which provides good heat-dissipation capability while achieving the function of support. The larger the thickness of the heat-dissipation layer 20 is, the better heat-dissipation of the supportive composite plate 100 becomes. Further, the thickness of the first supportive layer 101 and the thickness of the second supportive layer 102 both range between 30 to 150 micrometers (um), specifically 100 um.

A plurality of first openings 1011 are disposed on the first supportive layer 101 in the first direction D1 vertical to the heat-dissipation layer 20. A plurality of second openings 1021 are disposed on the second supportive layer 102 in the first direction D1. Both of the first opening 1011 and the second opening 1021 are disposed in the bending portion 12. A plurality of third openings 2021 are disposed in the bridge portion 202 in the first direction D1.

The first opening 1011 along the central line of the first direction D1 coincides with the second opening 1021 along the central line of the first direction D1. The third opening 2021 along the central line of the first direction D1 coincides with the second opening 1021 along the central line of the first direction D1.

The arrangement of the first opening 1011, the second opening 1021, and the third opening 2021 effectively reduces the stress generated by the supportive composite plate 100 at bending and further dissipates heat.

The spacing between the two adjacent first openings 1011 is 0.5 to 1 times of the length of the first opening 1011 in the first direction D1. The spacing between the two adjacent second openings 1021 is 0.5 to 1 times of the length of the second opening 1021 in the first direction D1. The spacing between the two adjacent third openings 2021 is 0.5 to 1 times of the length of the third opening 2021 in the first direction D1.

The rigid supportive layer 10 is made of stainless steel, aluminum (Al), and titanium (Ti). The heat-dissipation layer 20 is made of copper (Cu) and silver (Ag).

In the related art, the supportive layer and the heat-dissipation layer 20 in the supportive composite plate 100 are produced in a bonding process so that the overall thickness of the supportive composite plate 100 is heavy. In the present embodiment, the supportive composite plate 100 includes the rigid supportive layer 10 and the heat-dissipation layer 20. The rigid supportive layer 10 includes a first planar portion 11, a second planar portion 13, and a bending portion 12. The bending portion 12 is disposed between the first planar portion 11 and the second planar portion 13. The heat-dissipation layer 20 is embedded in the rigid supportive layer 10. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202. A plurality of first openings 1011 are disposed on the first supportive layer 101 in the first direction D1 vertical to the heat-dissipation layer 20. A plurality of second openings 1021 are disposed on the second supportive layer 102 in the first direction D1. Both of the first opening 1011 and the second opening 1021 are disposed in the bending portion 12. A plurality of third openings 2021 are disposed in the bridge portion 202 in the first direction D1. The first opening 1011 along the central line of the first direction D1 coincides with the second opening 1021 along the central line of the first direction D1. The third opening 2021 along the central line of the first direction D1 coincides with the second opening 1021 along the central line of the first direction D1. The heat-dissipation layer 20 is embedded in the rigid supportive layer 10 in the supportive composite plate 100. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202. The supportive composite plate 100, the rigid supportive layer 10, and the heat-dissipation layer 20 are integrally formed with a physical compression technique. Without affecting the function of a foldable display panel, the overall thickness of the supportive composite plate 100 is thinned in addition to a good supportive function, thereby, reducing the weight of the supportive composite plate 100 and improving the heat-dissipation capacity of the supportive composite plate 100. Besides, the arrangement of the first opening 1011, the second opening 1021, and the third opening 2021 effectively reduces the stress generated by the supportive composite plate 100 at bending and further dissipates heat.

### Embodiment 2

Please refer to FIG. 2 illustrating a schematic diagram of a supportive composite plate 100 according to a second embodiment of the present disclosure. The structure of the supportive composite plate 100 in the present embodiment is the same as or similar to the structure of the supportive composite plate 100 in the first embodiment. Otherwise, the difference is simply that a first opening 1011 penetrates a first supportive layer 101 and exposes one surface of a heat-dissipation layer 20 which is near the first supportive layer 101. A second opening 1021 penetrates a second supportive layer 102 and exposes one surface of the heat-dissipation layer 20 which is near the second supportive layer 102. Each of the first openings 1011 is displaced with each of the adjacent second openings 1021 in a first direction D1.

The first opening 1011 is simply arranged in the first supportive layer 101, and the second opening 1021 is simply arranged in a second supportive layer 102 in the present embodiment. Each of the first openings 1011 is displaced with each of the adjacent second openings 1021 in the first directions D1, which further reduces the stress generated while the supportive composite plate 100 is bent.

A plurality of third openings 2021 are disposed on a bridge portion 202 in the first direction D1. Each of the plurality of first openings 2021 is displaced with each of the adjacent second openings 1021 in the first directions D1.

In the related art, the supportive layer and the heat-dissipation layer 20 in the supportive composite plate 100 are produced in a bonding process so that the overall thickness of the supportive composite plate 100 is heavy. In the present embodiment, the supportive composite plate 100 includes the rigid supportive layer 10 and the heat-dissipation layer 20. The rigid supportive layer 10 includes a first planar portion 11, a second planar portion 13, and a bending portion 12. The bending portion 12 is disposed between the first planar portion 11 and the second planar portion 13. The heat-dissipation layer 20 is embedded in the rigid supportive layer 10. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202. The plurality of first openings 1011 are disposed on the first supportive layer 101 in the first direction D1 vertical to the heat-dissipation layer 20. The plurality of second openings 1021 are disposed on the second supportive layer 102 in the first direction D1. Both of the first opening 1011 and the second opening 1021 are disposed in the bending portion 12. The first opening 1011 penetrates the first supportive layer 101 and exposes one surface of the heat-dissipation layer 20 which is near the first supportive layer 101. The second opening 1021 penetrates the second supportive layer 102 and exposes one surface of the heat-dissipation layer 20 which is near the second supportive layer 102. Each of the first openings 1011 is displaced with each of the adjacent second openings 1021 in the first directions D1. The heat-dissipation layer 20 is embedded in the rigid supportive layer 10 in the supportive composite plate 100 as introduced above. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202. The supportive composite plate 100, the rigid supportive layer 10, and the heat-dissipation layer 20 are integrally formed with a physical compression technique. Without affecting the function of a foldable display panel, the overall thickness of the supportive composite plate 100 is thinned in addition to a good supportive function, thereby, reducing the weight of the supportive composite plate 100 and improving the heat-dissipation capacity of the supportive composite plate 100.

Compared with the the first embodiment, the stress generated at the bending of the supportive composite plate 100 is further reduced in the present embodiment which proposes that each of the first openings 1011 is displaced with each of the adjacent second openings 1021 in the first directions D1.

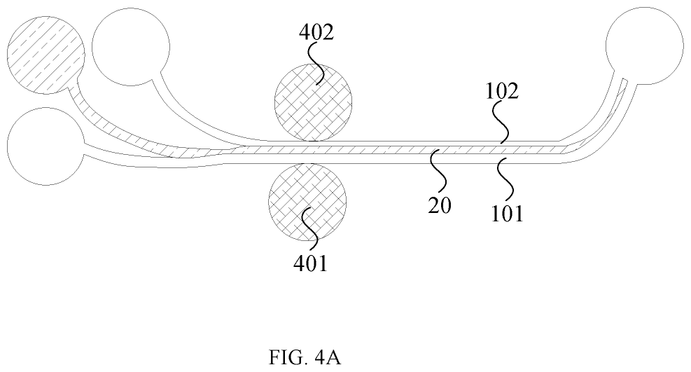

Please refer to FIG. 3 illustrating a flowchart of a fabrication method of a supportive composite plate 100 according to another embodiment of the present disclosure.

The fabrication method includes block S10, block S20, block S30, and block S40.

At block S10, a heat-dissipation layer 20 is stacked on a first supportive layer 101.

At block S20, a second supportive layer 102 is stacked on one side of the heat-dissipation layer 20 away from the first supportive layer 101.

At block S30, the first supportive layer 101, the heat-dissipation layer 20, and the second supportive layer 102 are rolled with a physical compression technique to form a first composite plate.

At block S40, the first composite plate arranged in a bending portion is patterned to form a supportive composite plate 100.

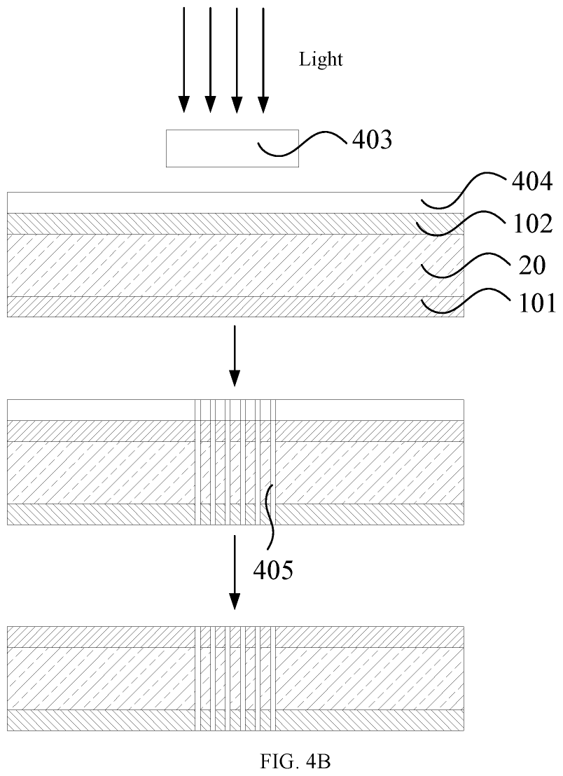

Please refer to FIG. 4A and FIG. 4B illustrating a schematic diagram of the shaped supportive composite plate 100 according to another embodiment of the present disclosure. Specifically, the process of shaping the supportive composite plate 100 is introduced as follows (the fabrication of the supportive composite plate 100 of the present embodiment as an example).

At first, the second coil of the heat-dissipation layer 20 is superimposed on the first coil of the first supportive layer 101. Subsequently, the third coil of the second supportive layer 102 is stacked on one side of the second coil away from the first coil. At this time, the thickness of each of the coils is not the thickness of the finished coils. Afterwards, a lower roller 401 of the first coil away from the second coil and an upper roller 402 of the second coil away from the third coil are rolled and extruded. At the same time, the discharge section of the above-mentioned coils is pulled, and the final rolling is made into three-layer laminated material of the first coil with the required thickness, the second coil with the required thickness, and the third coil with the required thickness. Finally, the three-layer laminated material is subjected to piece-cutting to fabricate the first composite plate, as FIG. 4A shows.

Preferably, the first coil and the the third coil are both made of stainless steel, aluminum (Al), and titanium (Ti), and the second coil is made of copper (Cu) and silver (Ag). The thickness of the first coil, the second coil, and the third coil is not limited in the present embodiment. Preferably, the thickness of the heat-dissipation layer 20 is greater than the thickness of the first supportive layer 101 or the thickness of the second supportive layer 102.

The fabrication of the first composite plate produces a bending portion and non-bending portions arranged on both sides of the bending portion where the first composite plate is disposed. One part of the first composite plate in the bending portion is patterned. A plurality of holes 405 arranged in an array are formed in the bending portion 12. The hole 405 penetrates the first supportive layer 101, the heat-dissipation layer 20, and the second supportive layer 102 completely. The process of patterning the first composite plate is introduced as follows:
firstly, coating a photoresist 404 on one side of a second supportive layer 102 away from a heat-dissipation layer 20;
secondly, exposing the photoresist 404 using a light cover 403;
thirdly, developing and etching a first composite plate to to form a plurality of holes 405 arranged in an array in the bending portion of the first composite plate;
finally, removing the photoresist 404 to obtain a supportive composite plate 100.

The hole 405 further reduces the stress generated when the supportive composite plate 100 is bent, as shown in FIG. 4B.

The present disclosure further proposes a display module. The display module includes a supportive composite plate 100 and a display panel disposed on the supportive composite plate 100 as introduced in either one of the above-mentioned embodiments. The supportive composite plate 100 is in conjunction with the display panel via an adhesive layer.

Further, the display module further includes an adhesive layer. The adhesive layer is arranged between the supportive composite plate 100 and the display panel. The adhesive layer is made of a solid-state optical glue.

The present embodiment proposes a supportive composite plate 100, a fabrication method of the supportive composite plate 100, and a display module. In the present embodiment, the supportive composite plate 100 includes the rigid supportive layer 10 and the heat-dissipation layer 20. The rigid supportive layer 10 includes a first planar portion 11, a second planar portion 13, and a bending portion 12. The bending portion 12 is disposed between the first planar portion 11 and the second planar portion 13. The heat-dissipation layer 20 is embedded in the rigid supportive layer 10. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202. The heat-dissipation layer 20 is embedded in the rigid supportive layer 10 in the supportive composite plate 100. The heat-dissipation layer 20 includes a first heat-dissipation portion 201, a second heat-dissipation portion 203, and a bridge portion 202. The first heat-dissipation portion 201 corresponds to the first planar portion 11. The second heat-dissipation portion 203 corresponds to the second planar portion 13. The bridge portion 202 corresponds to the bending portion 12. The first heat-dissipation portion 201 is connected to the second heat-dissipation portion 203 via the bridge portion 202. The overall thickness of the supportive composite plate 100 is thinned in addition to a good supportive function. Further, the weight of the supportive composite plate 100 is reduced, and the heat-dissipation capacity of the supportive composite plate 100 is improved as well.

Above are embodiments of the present invention, which does not limit the scope of the present invention. Any modifications, equivalent replacements or improvements within the spirit and principles of the embodiment described above should be covered by the protected scope of the invention.

What is claimed is:

1. A supportive composite plate, applied to a foldable display panel, comprising:
a rigid supportive layer, comprising a first planar portion, a second planar portion, and a bending portion arranged between the first planar portion and the second planar portion; and
a heat-dissipation layer, embedded in the rigid supportive layer and comprising a first heat-dissipation portion corresponding to the first planar portion, a second heat-dissipation portion corresponding to the second planar portion, and a bridge portion corresponding to the bending portion; the first heat-dissipation portion being connected to the second heat-dissipation portion via the bridge portion.

2. The supportive composite plate of claim 1, wherein the rigid supportive layer comprises a first supportive layer and a second supportive layer; the heat-dissipation layer is disposed between the first supportive layer and the second supportive layer; a thickness of the heat-dissipation layer is greater than a thickness of the first supportive layer or a thickness of the second supportive layer.

3. The supportive composite plate of claim 2, wherein a plurality of first openings are disposed on the first supportive layer in a first direction vertical to the heat-dissipation layer; a plurality of second openings are disposed on the second supportive layer in the first direction;
both of the first opening and the second opening are disposed in the bending portion.

4. The supportive composite plate of claim 3, wherein the first opening penetrates the first supportive layer and exposes a surface of the heat-dissipation layer which is near the first supportive layer; the second opening penetrates the second supportive layer and exposes a surface of the heat-dissipation layer which is near the second supportive layer;
each of the first openings is displaced with each of the adjacent second openings in the first direction.

5. The supportive composite plate of claim 3, wherein the first opening along a central line of the first direction coincides with the second opening along the central line of the first direction.

6. The supportive composite plate of claim 5, wherein a plurality of third openings are disposed in the bridge portion in the first direction; the third opening along the central line of the first direction coincides with the second opening along the central line of the first direction.

7. The supportive composite plate of claim 5, wherein a spacing between the two adjacent first openings is 0.5 to 1 times of a length of the first opening in the first direction.

8. The supportive composite plate of claim 1, wherein a material for the rigid supportive layer is stainless steel, aluminum (Al), and titanium (Ti); a material for the heat-dissipation layer is copper (Cu) and silver (Ag).

9. A fabrication method of a supportive composite plate, comprising:
stacking a heat-dissipation layer on a first supportive layer;
stacking a second supportive layer on a side of the heat-dissipation layer away from the first supportive layer;
rolling the first supportive layer, the heat-dissipation layer, and the second supportive layer with a physical compression technique to form a first composite plate; and
patterning the first composite plate arranged in a bending portion to form the supportive composite plate.

10. The fabrication method of claim 9, wherein a thickness of the heat-dissipation layer is greater than a thickness of the first supportive layer or a thickness of the second supportive layer.

11. The fabrication method of claim 9, wherein a material for the first supportive layer and for the second supportive layer is stainless steel, aluminum (Al), and titanium (Ti); a material for the heat-dissipation layer is copper (Cu) and silver (Ag).

12. A display module, comprising:
a supportive composite plate, comprising:
a rigid supportive layer, comprising a first planar portion, a second planar portion, and a bending portion arranged between the first planar portion and the second planar portion; and
a heat-dissipation layer, embedded in the rigid supportive layer and comprising a first heat-dissipation portion corresponding to the first planar portion, a second heat-dissipation portion corresponding to the second planar portion, and a bridge portion corresponding to the bending portion; the first heat-dissipation portion being connected to the second heat-dissipation portion via the bridge portion; and
a display panel arranged on the supportive composite plate.

13. The display module of claim 12, wherein the rigid supportive layer comprises a first supportive layer and a second supportive layer; the heat-dissipation layer is disposed between the first supportive layer and the second supportive layer; a thickness of the heat-dissipation layer is greater than a thickness of the first supportive layer or a thickness of the second supportive layer.

14. The display module of claim 13, wherein a plurality of first openings are disposed on the first supportive layer in a first direction vertical to the heat-dissipation layer; a plurality of second openings are disposed on the second supportive layer in the first direction; both of the first opening and the second opening are disposed in the bending portion.

15. The display module of claim 14, wherein the first opening penetrates the first supportive layer and exposes a surface of the heat-dissipation layer which is near the first supportive layer; the second opening penetrates the second supportive layer and exposes a surface of the heat-dissipation layer which is near the second supportive layer;
each of the first openings is displaced with each of the adjacent second openings in the first direction.

16. The display module of claim 14, wherein the first opening along a central line of the first direction coincides with the second opening along the central line of the first direction.

17. The display module of claim 16, wherein a plurality of third openings are disposed in the bridge portion in the first direction; the third opening along the central line of the first direction coincides with the second opening along the central line of the first direction.

18. The display module of claim 16, wherein a spacing between the two adjacent first openings is 0.5 to 1 times of a length of the first opening in the first direction.

19. The display module of claim 12, wherein a material for the rigid supportive layer is stainless steel, aluminum (Al), and titanium (Ti); a material for the heat-dissipation layer is copper (Cu) and silver (Ag).

20. The display module of claim 12, wherein the display module further comprises an adhesive layer; the adhesive layer is arranged between the supportive composite plate and the display panel;
a material for the adhesive layer is a solid-state optical glue.
